(19) United States
(12) Patent Application Publication
(10) Pub. No.: US 2005/0056862 A1
(43) Pub. Date: Mar. 17, 2005

(54) Photo-diode and method for fabricating the same

(76) Inventor: Chan-Yong Park, Yuseong-gu (KR)

Correspondence Address: KNOBBE MARTENS OLSON & BEAR LLP, 2040 MAIN STREET, FOURTEENTH FLOOR, IRVINE, CA, 92614, US

(21) Appl. No.: 10/802,593

(22) Filed: Mar. 17, 2004

(30) Foreign Application Priority Data
Sep. 16, 2003 (KR) 10-2003-0064115

(51) Int. Cl. H01L 21/00; H01L 31/0328

(52) U.S. Cl. 257/184; 438/48; 257/186

(57) ABSTRACT

Disclosed is a photodiode and a method for fabricating the same for reducing excessive electric field applied to a mesa-etched region, thereby providing a stable operation and a longer durability. The photodiode includes a substrate, a first conduction type buffer layer formed on the substrate, an amplifying layer having a superlattice structure formed on the first conduction type buffer layer to form a mesa structure, a second conduction type field controlling layer formed on the amplifying layer, a second conduction type ion injection layer formed within the field controlling layer, a second conduction type light-absorbing layer formed on the field controlling layer, a second conduction type buffer layer formed on the light-absorbing layer, and a first electrode and a second electrode formed to electrically contact the first conduction type buffer layer and the second conduction type buffer layer, respectively.

### CROSS-REFERENCE TO RELATED APPLICATIONS

This application claims the benefit of Korean Application No. P2003-0064115, filed on Sep. 16, 2003, which is hereby incorporated by reference as if fully set forth herein.

### BACKGROUND OF THE INVENTION

1. Field of the Invention

The present invention relates to a photodiode used as a photodetector in high-speed optical communications, and more particularly, to a structure of a mesa-type avalanche photodiode and a method for fabricating the same. Although the present invention is suitable for a wide scope of applications, it is particularly suitable for reducing excessive electric field applied to a mesa-etched region, thereby providing a stable operation and a longer durability.

2. Discussion of the Related Art

Generally, in optical communications, a transmitting party uses a luminescence photodiode so as to convert an electrical signal to an optical signal, thereby transmitting the converted optical signal to a receiving party through a transmission channel.

In optical communications, the receiving party uses the photodiode as a photodetector. Herein, the avalanche photodiode (APD) is most extensively used. The avalanche photodiode (APD) is a device having a carrier injected in a region where a high electric field is applied to provide an amplification resulting from an avalanche effect. The APD is generally categorized into two types: a flat type avalanche photodiode and a mesa-type avalanche photodiode. The two types of APD's commonly have a multi-layered structure of an amplifying layer and a light-absorbing layer deposited on a semiconductor substrate.

The related art avalanche photodiode (APD) will now be described in detail with reference to the accompanying drawings.

FIG. 1 illustrates a cross-sectional view of the related art avalanche photodiode shown in I. Watanabe et al., “Gain-Bandwidth Product Analysis of InAlGaAs—InAlAs Superlattice Avalanche Photodiodes”, IEEE Photonics Technology Letters, Vol. 8, No. 2, pp. 269-271, 1996.

In the related art method for fabricating an avalanche photodiode, as shown in FIG. 1, an amplifying layer 4 having a superlattice structure including a high concentration n-type InP substrate 1, a high concentration n-type InP buffer layer 2, a high concentration n-type InAlAs buffer layer 3, and undoped InAlAs and InGaAlAs layers serially deposited on one another is provided. Then, a high concentration p-type field controlling layer 5, a low concentration p-type InGaAs light-absorbing layer 6, a high concentration p-type InP field buffer 7, and a high concentration p-type InGaAs ohmic contact layer 8 are serially deposited on one another by a metal-organic chemical vapor deposition (MOCVD) method or a gas source molecular beam epitaxy (GSMBE) method.

Thereafter, although not shown in the drawings, a photoresist layer is deposited on the p-type InGaAs ohmic contact layer 8, on which a region to be mesa-etched is determined after an exposure and development process by using a mask. Subsequently, the high concentration n-type InAlAs buffer layer 3, the amplifying layer 4, the high concentration field controlling layer 5, the low concentration p-type InGaAs light-absorbing layer, the high concentration p-type InP field buffer layer 7, and the high concentration p-type InGaAs ohmic contact layer 8 are selectively removed so as to expose the high concentration n-type InP buffer layer 2, thereby forming a mesa structure.

In addition, a surface protection layer 9 is formed on the entire surface of the substrate having the mesa structure. The surface protection layer 9 is selectively removed so as to expose the surface of the high concentration n-type InP buffer layer 2 and the surface of the high concentration p-type InGaAs ohmic contact layer 8, and then, a plurality of contact holes are formed. Subsequently, an n-electrode 11 and a p-electrode 10 are formed to electrically contact the high concentration n-type InP buffer layer 2 and the high concentration p-type InGaAs ohmic contact layer 8, respectively, through each of the contact holes.

Accordingly, the above-described method for fabricating the related art avalanche photodiode, shown in FIG. 1, has the following advantages.

Since a pn junction is formed by a crystal growth process of a semiconductor, the thickness of the amplifying layer 4 can be easily controlled and the amplifying layer 4 can be formed to have a superlattice structure, thereby improving the avalanche photodiode by enhancing the amplifying characteristic and reducing excess noise factors. Also, a mesa-etching structure, which reduces capacitance, is used herein, thereby enabling high speed operations.

However, the related art method for fabricating an avalanche photodiode is disadvantageous in that a high leakage current may occur because an electric field is excessively applied to the mesa-etching surface, thereby reducing the durability of the photodiode.

Accordingly, in order to resolve such problems and to improve durability, the APD technology has been further developed.

FIG. 2 illustrates a cross-sectional view of another related art avalanche photodiode shown in C. Y. Park et al., “Fabrication of INGaAs/InP avalanche photodiodes by reactive ion etching using CH₄/H₂ gases”, Journal of Vacuum Science Technologies B, Vol. 13, No. 3, pp. 974-977, 1995, wherein a method for improving the durability of the mesa-type avalanche photodiode of FIG. 1 is proposed.

A related method for fabricating an avalanche photodiode will now be described in detail with reference to FIG. 2.

A high concentration n-type InP buffer layer 22, an undoped InGaAs light-absorbing layer 23, a multi-layered InGaAsP gradation layer 24, and an n-type InP field controlling layer 25 are serially deposited on a high concentration n-type InP substrate by using an epitaxial semiconductor growth device, such as MOCVD.

As shown in region ‘A’ of FIG. 2, the field controlling layer 25 is formed to have a different thickness in order to form a charge plate. More specifically, a photoresist pattern (not shown) is deposited on the field controlling layer 25 by using a photolithography process. Then, a portion of the exposed field controlling layer 25 is etched by the photoresist pattern.

Additionally, p-type impurities are dispersed on a regrown wafer, by using the epitaxial semiconductor growth device, such as MOCVD, and the undoped InP deposited on the field controlling layer 25 to form an InP amplifying layer 26 and a high concentration p-type InP contact layer 27.

Subsequently, although not shown in the drawing, a photoresist layer is deposited on the high concentration p-type InP contact layer 27. A region to be mesa-etched is then determined after an exposure and development process by using a mask. Afterwards, the InGaAs light-absorbing layer 23, the multi-layered InGaAsP gradation layer 24, the n-type InP field controlling layer 25, the InP amplifying layer 26, and the high concentration p-type InP contact layer 27 are selectively removed to expose the surface of the high concentration n-type InP buffer layer 22, thereby forming a mesa-structure. The mesa-etching process is carried out in a ring form, and is formed on the etched area.

Furthermore, a surface protection layer 28 is formed, the entire surface of the substrate. The surface protection layer 28 is then selectively removed to expose the surface of the high concentration p-type InP contact layer 27, and then, a plurality of contact holes are formed. Subsequently, a p-electrode 29 is formed to electrically contact the high concentration p-type InP contact layer 27, and an n-electrode 30 is formed on the lower surface of the high concentration n-type InP substrate 21, thereby forming the avalanche photodiode.

As described above, in the avalanche photodiode having a charge plate, when a high electric field for amplifying electric current is applied, a high electric field is applied to the central region (region ‘A’ of FIG. 2) of the field controlling layer 25 having a larger thickness, thereby amplifying the optical current occurring from the projected signals. However, a low electric field is formed on the surrounding region thereof, and so the current flow in the mesa-etching region (region ‘B’ of FIG. 2) is low. And thus, degradation does not occur.

However, the structure of the related art avalanche photodiode shown in FIG. 2 is advantageous in that the decrease in reliability of the photodiode occurring on the mesa-etched surface can be prevented. However, the related art avalanche photodiode is disadvantageous in that the avalanche photodiode is formed by etching the field controlling layer first, and then, carrying out a semiconductor regrowth process. When such a regrowth process is carried out, oxygen (O) and silicon (Si) atoms may be stacked on the regrowth interface (shown in FIG. 2 and marked as oblique lines).

When the oxygen (O) and silicon (Si) atoms are stacked on the regrowth interface, the electric field cannot be uniformly dispersed within the semiconductor device, thereby reducing product durability. Since the regrowth interface is formed between the amplifying layer, having a high electric field of about ˜600 kV/cm applied thereon, and the field controlling layer, the regrowth process eventually reduces the durability of the avalanche photodiode.

FIG. 3 illustrates results from an experiment on oxygen and silicon atoms being stacked on the regrowth interface.

The data shown in FIG. 3 are results from a quantitative analysis according to the depth of a regrown wafer from the surface of the semiconductor layer by using a secondary ion mass spectroscopy (SIMS). As shown in FIG. 3, a large amount of oxygen and silicon atoms is stacked, and accordingly, the fabrication process of the photodiode is very much affected.

Therefore, when using the avalanche photodiode for high speed optical communications, it is preferable to use a mesa-type avalanche photodiode, which is most advantageous. Nevertheless, a newly improved avalanche photodiode structure is required, so as to prevent the reliability of the photodiode from being affected.

### SUMMARY OF THE INVENTION

Accordingly, the present invention is directed to a photodiode and a method for fabricating the same that substantially obviate one or more problems due to limitations and disadvantages of the related art.

An object of the present invention is to provide a photodiode and a method for fabricating the same in a mesa-type avalanche photodiode for high speed optical communications, which can repress an electric field applied to a mesa-etched surface to prevent a regrowth interface from being formed.

A further object of the present invention is to provide a photodiode and a method for fabricating the same in a mesa-type avalanche photodiode for high speed optical communications, which can improve reliability of the photodiode.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a photodiode includes a substrate, a first conduction type buffer layer formed on the substrate, an amplifying layer having a superlattice structure formed on the first conduction type buffer layer to form a mesa structure, a second conduction type field controlling layer formed on the amplifying layer, a second conduction type ion injection layer formed within the field controlling layer, a second conduction type light-absorbing layer formed on the field controlling layer, a second conduction type buffer layer formed on the light-absorbing layer, and a first electrode and a second electrode formed to electrically contact the first conduction type buffer layer and the second conduction type buffer layer, respectively.

Herein, the photodiode further includes a second conduction type ohmic contact layer formed between the second conduction type buffer layer and the second electrode.

Also, the photodiode further includes a passivation layer formed on an entire surface of the substrate including the second conduction type ohmic contact layer, wherein the passivation layer comprises a plurality of contact holes enabling the first electrode to electrically contact the first conduction type buffer layer and the second electrode to electrically contact the second conduction type ohmic contact layer.

The photodiode further includes an anti-reflection layer formed on a lower surface of the substrate.

Herein, the first conduction type buffer layer, the second conduction type field controlling layer, and the second conduction type buffer layer are formed of an InP semiconductor layer, and the second conduction type light-absorbing layer is formed of an InGaAs semiconductor layer.

The first conduction type buffer layer is formed of the InP semiconductor layer and an InAlAs semiconductor layer.

A total charge density of the second conduction type ion injection layer and the second conduction type field controlling layer is 3×1012/cm²±20%, and a charge density of an edge region, where the ion injection layer is not formed, is 2×1012/cm²±20%.

The amplifying layer having the superlattice structure is either formed of one of the InAlAs semiconductor layer and an InAlGaAs semiconductor layer, or formed of the InAlAs semiconductor layer and the InAlGaAs semiconductor layer alternately deposited on each other.

Also, the second electrode is formed in a ring structure so as to project a plurality of optical signals toward the second electrode.

Herein, the substrate is formed of one of a first conduction type InP semiconductor layer and a semi-insulation InP semiconductor layer.

In another aspect of the present invention, a method for fabricating a photodiode includes preparing a substrate, serially forming a first conduction type buffer layer, an amplifying layer having a superlattice structure, a second conduction type field controlling layer, and a surface protection layer on the substrate, injecting ions into the field controlling layer so as to form a second conduction type ion injection layer, removing the surface protection layer and serially forming a second conduction type light-absorbing layer, a second conduction type field buffer layer, and a second conduction type ohmic contact layer on the field controlling layer, selectively removing the second conduction type ohmic contact layer, the second conduction type field buffer layer, the second conduction type light-absorbing layer, the second conduction type field controlling layer, and the amplifying layer having the superlattice structure, based on the ion injection layer, so as to expose a surface of the first conduction type buffer layer, thereby forming a mesa structure, forming a passivation layer on an entire surface of the substrate, so as to form a plurality of contact holes on the ohmic contact layer and the first conduction type buffer layer, and forming a first electrode and a second electrode electrically contacting the first conduction type buffer layer and the second conduction type ohmic contact layer, respectively, through the contact holes.

Herein, the forming an ion injection layer further includes ion injecting impurities such as beryllium (Be) or magnesium (Mg) into the field controlling layer, and activating the injected ions by treating the substrate with a heating process.

The heating process is carried out at a temperature in the range of 600 to 700 degrees Celsius (° C).

Also, the method for fabricating the photodiode further includes carrying out a lapping process and a polishing process, so as to reduce a thickness of the photodiode.

The method for fabricating the photodiode further includes forming an anti-reflection layer on a lower surface of the substrate.

Herein, the first conduction type buffer layer, the second conduction type field controlling layer, and the second conduction type buffer layer are formed of an InP semiconductor layer, and the second conduction type light-absorbing layer and the second conduction type ohmic contact layer are formed of an InGaAs semiconductor layer.

The first conductive type buffer layer is formed by depositing the InP semiconductor layer and an InAlAs semiconductor layer, and the InAlAs semiconductor layer is removed when forming the mesa structure.

A total charge density of the second conduction type ion injection layer and the second conduction type field controlling layer is less than or equal to 3×1012/cm²±20%, and a charge density of an edge region, where the ion injection layer is not formed, is 2×1012/cm²±20%.

Herein, the amplifying layer having the superlattice structure is either formed of one of the InAlAs semiconductor layer and an InAlGaAs semiconductor layer, or formed of the InAlAs semiconductor layer and the InAlGaAs semiconductor layer alternately deposited on each other.

In a further aspect of the present invention, a method for fabricating a photodiode includes preparing a substrate, serially forming a first conduction type buffer layer, an amplifying layer having a superlattice structure, a second conduction type field controlling layer, a second conduction type light-absorbing layer, a second conduction type field buffer layer, and a second conduction type ohmic contact layer on the substrate, injecting ions into the field controlling layer so as to form a second conduction type ion injection layer, selectively removing the second conduction type ohmic contact layer, the second conduction type field buffer layer, the second conduction type light-absorbing layer, the second conduction type field controlling layer, and the amplifying layer having the superlattice structure, based on the ion injection layer, so as to expose a surface of the first conduction type buffer layer, thereby forming a mesa structure, forming a passivation layer on an entire surface of the substrate, so as to form a plurality of contact holes on the ohmic contact layer and the first conduction type buffer layer, and forming a first electrode and a second electrode electrically contacting the first conduction type buffer layer and the second conduction type ohmic contact layer, respectively, through the contact holes.

The method further includes forming an anti-reflection layer on a lower surface of the substrate.

Herein, the first conduction type buffer layer, the second conduction type field controlling layer, and the second conduction type buffer layer are formed of an InP semiconductor layer, and the second conduction type light-absorbing layer and the second conduction type ohmic contact layer are formed of an InGaAs semiconductor layer.

The first conductive type buffer layer is formed by depositing the InP semiconductor layer and an InAlAs semiconductor layer, and the InAlAs semiconductor layer is removed when forming the mesa structure.

A total charge density of the second conduction type ion injection layer and the second conduction type field controlling layer is less than or equal to 3×1012/cm²±20%, and a charge density of an edge region, where the ion injection layer is not formed, is 2×1012/cm²±20%.

The amplifying layer having the superlattice structure is either formed of one of the InAlAs semiconductor layer and an InAlGaAs semiconductor layer, or formed of the InAlAs semiconductor layer and the InAlGaAs semiconductor layer alternately deposited on each other.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention. In the drawings;

FIG. 1 illustrates a cross-sectional view of the related art avalanche photodiode.

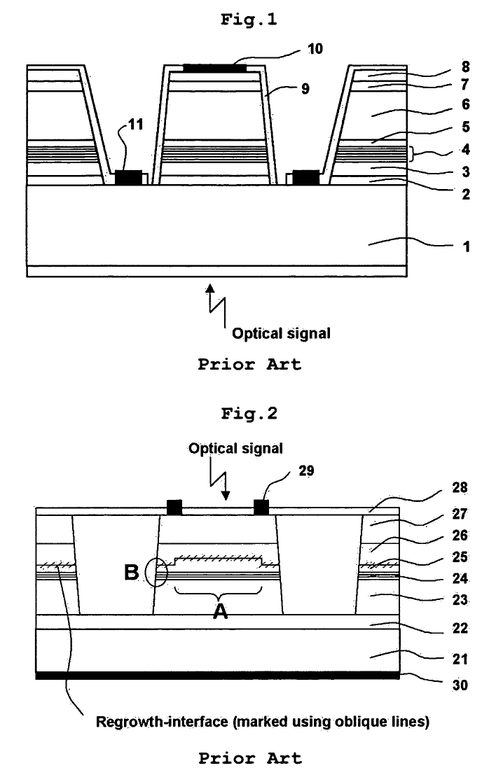

FIG. 2 illustrates a cross-sectional view of another related art avalanche photodiode.

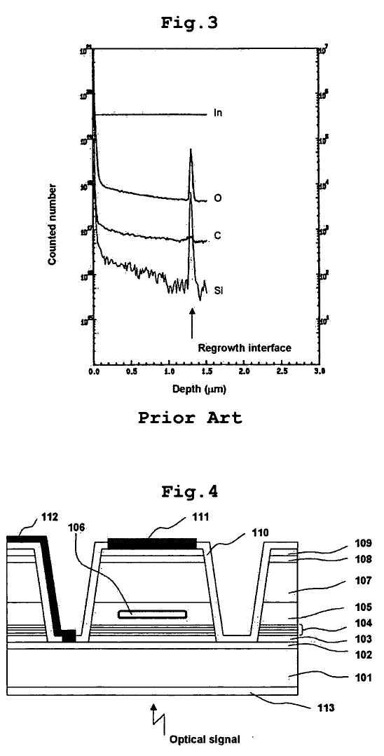

FIG. 3 is a graph illustrating the results of a quantitative analysis according to the depth of a related art avalanche photodiode from the surface of a semiconductor layer.

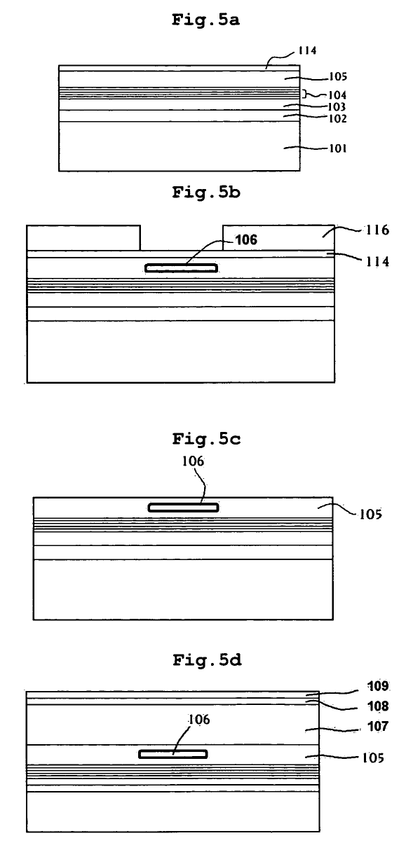

FIG. 4 illustrates a cross-sectional view of an avalanche photodiode according to the present invention.

FIGS. 5A to 5H are cross-sectional views illustrating the process steps of fabricating an avalanche photodiode according to a first embodiment of the present invention.

FIGS. 6A to 6F are cross-sectional views illustrating the process steps of fabricating an avalanche photodiode according to a second embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

A photodiode and a method for fabricating the same according to a preferred embodiment of the present invention will be described with reference to the accompanied drawings.

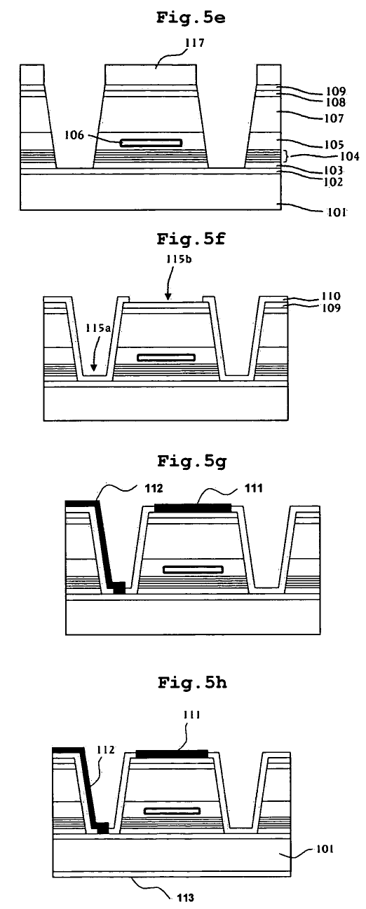

FIG. 4 illustrates a cross-sectional view of an avalanche photodiode according to the present invention.

As shown in FIG. 4, in the photodiode according to the present invention, an n-type InP buffer layer 102 is formed on an n-type InP substrate 101, in order to facilitate a crystal growth in a later process. Subsequently, an n-type InAlAs buffer layer 103 having a mesa structure for facilitating the growth of superlattice components in a later process, an amplifying layer 104 having a superlattice structure formed of undoped InAlAs and InGaAlAs layers for amplifying signal currents alternately deposited on one another, a p-type InP field controlling layer 105 for reducing the level of electric field applied to the light-absorbing layer, a p-type InGaAs light-absorbing layer 107 absorbing optical signals and converting the optical signals to electric current, a p-type InP field buffer layer 108, and a p-type InGaAs ohmic contact layer 109 for reducing electric contact resistivity with a p-electrode are sequentially deposited on the n-type InP buffer layer 102.

In addition, an ion injection layer 106 is partially formed on a central region within the p-type InP field controlling layer 105. Also, in the mesa structure having the above-described structure, a surface protection layer 110 is formed on the entire surface of the substrate so that a plurality of contact holes can be formed between the p-type InGaAs ohmic contact layer 109 and the n-type InP buffer layer 102. Then, a p-electrode 111 and an n-electrode 112 are formed on the surface protection layer 110 so as to electrically contact the p-type InGaAs ohmic contact layer 109 and the n-type InP buffer layer 102, respectively. Then, an anti-reflection layer 113 is formed on the lower surface of the n-type InP substrate 101, so as to prevent the applied light from being reflected.

Herein, the n-Inp buffer layer 102 is formed of the same material as that of the n-InP substrate 101, thereby enabling the semiconductor layer, which is to be grown in a later process, to be easily connected to the substrate. Also, the n-InAlAs buffer layer 103 is required for facilitating the growth of the InAlAs and InAlGaAs layers of the amplifying layer 104 having the superlattice structure. In addition, the amplifying layer 104 formed of a plurality of InAlAs and InAlGaAs layers alternately deposited on one another and grown to form the superlattice form, and amplifying signal current. Also, in order to amplify the current by an avalanche phenomenon, a high electric field of ˜600 kV/cm±10% is applied to the amplifying layer 105.

A light-absorbing layer 107 is formed of InGaAs, which has a low band-gap for absorbing light having a long wavelength used in optical communications. And, since the band-gap is low, when a high electric field of at least 200 kV/cm is applied, leakage current resulting from a tunneling effect is highly increased, thereby deteriorating photodiode characteristics. Therefore, in order to prevent the tunneling effect, a p-InP field controlling layer 105 is required to reduce electric field to a level less than or equal to 200 kV. In order to satisfy such conditions (i.e., the conditions of supplying sufficient electric field to the amplifying layer and reducing the electric field applied to the light-absorbing layer), a charge density (i.e., carrier concentration×thickness) of the p-InP field controlling layer 105 should be about 3.0×1012/cm²±20%. Under such conditions, the electric field of the light-absorbing layer is maintained at a level equal to or less than 200 kV/cm, whereas, a high level of electric field of about ˜600 kV/cm±20% is applied to the amplifying layer 104.

In the structure of the photodiode according to the present invention, shown in FIG. 4, the amplifying layer 104 is not necessarily required to be formed in a superlattice structure. Instead of the superlattice structure, the amplifying layer 104 may also be formed of a single InAlAs or InAlGaAs layer.

Also, the ohmic contact layer 109 is not necessarily required in the structure of the photodiode according to the present invention. In this case, however, the p-InP buffer layer 108 must be formed, which acts as the ohmic contact layer 109. Similarly, the p-InP buffer layer 108 can be omitted. However, in this case, the ohmic contact layer 109 must be included in the structure of the photodiode according to the present invention.

In addition, as shown in FIG. 4, the p-electrode 111 may be formed in a ring structure, in order to make the optical signals to be projected towards the p-electrode 111. In this case, the anti-reflection layer 113 formed on the substrate 101 can be omitted, thereby reducing the fabrication cost.

Moreover, the substrate 101 can be formed of a semi-insulation InP substrate instead of the n-InP substrate.

Furthermore, the n-type and the p-type of FIG. 4 each refer to a first conduction type and a second conduction type, respectively.

A method for fabricating the photodiode according to the present invention will now be described in detail with reference to the accompanying drawings.

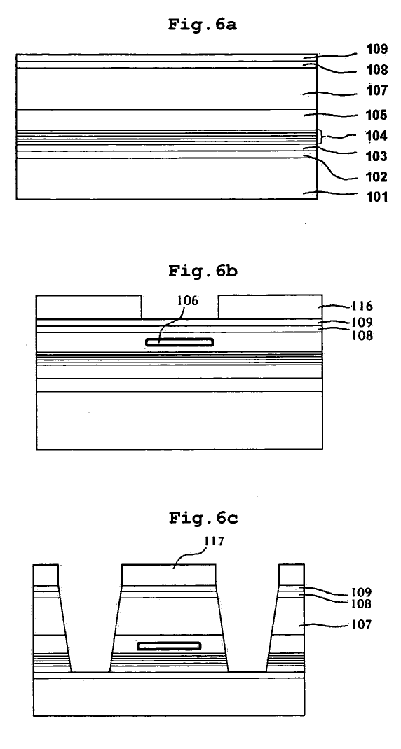

FIGS. 5A to 5H are cross-sectional views illustrating the process steps of fabricating an avalanche photodiode according to a first embodiment of the present invention.

As shown in FIG. 5A, an n-InP buffer layer 102, an n-InAlAs buffer layer 103, an amplifying layer 104 having a superlattice structure formed of undoped InAlAs and InGaAlAs layers alternately deposited on one another, a p-InP field controlling layer 105, and a p-InGaAs surface protection layer 114 formed on the p-InP field controlling layer 105 are serially deposited on an n-InP substrate 101. Herein, the surface protection layer 114 is formed to protect the surface of the p-InP field controlling layer 105 when injecting impurity ions and heat-treating the p-InP field controlling layer 105 in a later process.

As shown in FIG. 5B, a photoresist layer 116 is deposited on the p-InGaAs surface protection layer 114, which is then treated with an exposure and development process using a photolithography method in order to determine an ion injection region. Then, p-type impurity ions, such as beryllium (Be) and magnesium (Mg), are injected in the central region of the p-InP field controlling layer 105. Due to the ion injection process, the crystal characteristic of the p-InP field controlling layer 105 may be destroyed. Thus, an ion injection layer 106 is formed by a heat-treating process in order to restore the crystal characteristic of the p-InP field controlling layer 105 and to activate the injected ions. Herein, a silicon oxide (SiO₂) layer or a silicon nitride (SiNₓ) can be used instead of the photoresist layer 116, and the temperature range for the heat-treating process is from about 600 to 700 degrees Celsius (° C.).

Subsequently, with reference to FIG. 5C, the photoresist layer 116 and the p-InGaAs surface protection layer 114 are removed. And, as shown in FIG. 5D, a p-InGaAs light-absorbing layer 105, a p-InP field buffer layer 108, and a p-InGaAs ohmic contact layer 109 are serially formed on the p-InP field controlling layer 105.

As shown in FIG. 5E, a photoresist pattern 117 is formed on the p-InGaAs ohmic contact layer 109 through the exposure and development process. Then, based on the ion injection layer 106, the p-InGaAs ohmic contact layer 109, the p-InP field buffer layer 108, the InGaAs light-absorbing layer 107, the p-InP field controlling layer 105, the amplifying layer 104 having the superlattice structure, and the n-InAlAs buffer layer 103 on both regions are selectively removed to expose the surface of the n-InP buffer layer 102, thereby forming a mesa structure.

Then, as shown in FIG. 5F, a passivation layer 110 formed of silicon nitride (SiNₓ), for example, is deposited on the entire surface of the substrate having the mesa structure. Subsequently, the passivation layer 110 is selectively removed to exposed the surfaces of the p-InGaAs ohmic contact layer 109 and the n-InP buffer layer 102, each formed on the ion injection layer 106, then a plurality of contact holes 115a and 115b are formed.

As shown in FIG. 5G, an n-electrode 112 and a p-electrode 111 are formed. Herein, a conductive material, such as metal, is deposited on the entire surface of the passivation layer 110, so that the n-InP buffer layer 102 and the p-InGaAs ohmic contact layer 109 can be electrically contacted to the n-electrode 112 and the p-electrode 111, respectively, through the contact holes 115a and 115b.

As shown in FIG. 5H, in order to reduce the thickness of the photodiode, a lapping process and a polishing process are carried out, and then, an anti-reflection layer 113 is formed on the lower surface of the n-InP substrate 101 on which light is projected. Herein, the anti-reflection layer 113 may be formed either on the entire lower surface of the n-InP substrate 101, or partially on the regions within the mesa structure.

Meanwhile, the photodiode according to the present invention having the structure described in FIG. 4 may be fabricated by another method.

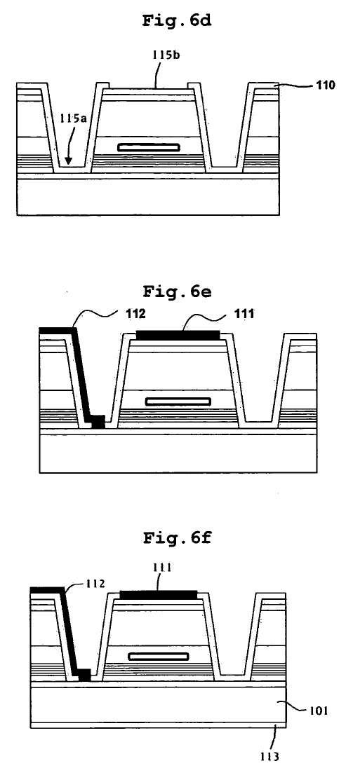

FIGS. 6A to 6F are cross-sectional views illustrating the process steps of fabricating an avalanche photodiode according to a second embodiment of the present invention.

As shown in FIG. 6A, an n-InP buffer layer 102, an n-InAlAs buffer layer 103, an amplifying layer 104 having a superlattice structure formed of undoped InAlAs and InGaAlAs layers alternately deposited on one another, a p-InP field controlling layer 105, an InGaAs light-absorbing layer 107, a p-InP field buffer layer 108, and a p-InGaAs ohmic contact layer 109 are serially deposited on an n-InP substrate 101.

As shown in FIG. 6B, a photoresist layer 116 is deposited on the p-InGaAs ohmic contact layer 109, which is then treated with an exposure and development process using a photolithography method in order to determine an ion injection region. Then, p-type impurity ions, such as beryllium (Be) and magnesium (Mg), are injected in the central region of the p-InP field controlling layer 105. Due to the ion injection process, the crystal characteristic of the semiconductor layer may be destroyed. Thus, an ion injection layer 106 is formed by a heat-treating process in order to restore the crystal characteristic of the semiconductor layer and to activate the injected ions. Herein, a silicon oxide (SiO₂) layer or a silicon nitride (SiNₓ) can be used instead of the photoresist layer 116, and the temperature range for the heat-treating process is from about 600 to 700 degrees Celsius (° C.).

Subsequently, as shown in FIG. 6C, the photoresist layer 116 is removed, and a photoresist pattern 117 is formed on the p-InGaAs ohmic contact layer 109. Then, based on the ion injection layer 106, the p-InGaAs ohmic contact layer 109, the p-InP field buffer layer 108, the InGaAs light-absorbing layer 107, the p-InP field controlling layer 105, the amplifying layer 104 having the superlattice structure, and the n-InAlAs buffer layer 103 on both regions are selectively removed to expose the surface of the n-InP buffer layer 102, thereby forming a mesa structure.

Then, as shown in FIG. 6D, a passivation layer 110 formed of silicon nitride (SiNₓ), for example, is deposited on the entire surface of the substrate having the mesa structure. Subsequently, the passivation layer 110 is selectively removed to expose the surfaces of the p-InGaAs ohmic contact layer 109 and the n-InP buffer layer 102, each formed on the ion injection layer 106, then a plurality of contact holes 115a and 115b are formed.

As shown in FIG. 6E, an n-electrode 112 and a p-electrode 111 are formed. Herein, a conductive material, such as metal, is deposited on the entire surface of the passivation layer 110, so that the n-InP buffer layer 102 and the p-InGaAs ohmic contact layer 109 can be electrically contacted to the n-electrode 112 and the p-electrode 111, respectively, through the contact holes 115a and 115b.

As shown in FIG. 6F, an anti-reflection layer 113 is formed on the lower surface of the n-InP substrate 101 on which light is projected. Herein, the anti-reflection layer 113 may be formed either on the entire lower surface of the n-InP substrate 101, or partially on the regions within the mesa structure.

The above-described structure of the photodiode and the method for fabricating the same according to the present invention have the following advantages.

By forming an ion injection layer in the field controlling layer, a high electric field is applied to the central region of the photodiode where the ion injection layer is formed, so as to produce a sufficient amplification resulting from an avalanche phenomenon. On the other hand, the level of electric field on the edge region of the photodiode can be decreased, thereby reducing leakage current on the mesa-etching surface and improving product durability.

In the related art photodiode, a regrowth interface is formed between the amplification layer having an electric field of about 500 to 600 kV applied thereon and the field controlling layer, thereby reducing the durability of the photodiode. However, in the first embodiment of the present invention, since the regrowth interface is formed between a light-absorbing layer having a low electric field of less than 200 kV and a field controlling layer, the durability of the photodiode can be highly improved. On the other hand, in the second embodiment of the present invention, by carrying out a single crystal growth process, the regrowth interface formed in the related art photodiode can be omitted.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A photodiode, comprising:
a substrate;
a first conduction type buffer layer formed on the substrate;
an amplifying layer having a superlattice structure formed on the first conduction type buffer layer to form a mesa structure;
a second conduction type field controlling layer formed on the amplifying layer;
a second conduction type ion injection layer formed within the field controlling layer;
a second conduction type light-absorbing layer formed on the field controlling layer;
a second conduction type buffer layer formed on the light-absorbing layer; and
a first electrode and a second electrode formed to electrically contact the first conduction type buffer layer and the second conduction type buffer layer, respectively.

2. The photodiode according to claim 1, further comprising a second conduction type ohmic contact layer formed between the second conduction type buffer layer and the second electrode.

3. The photodiode according to claim 2, further comprising a passivation layer formed on an entire surface of the substrate including the second conduction type ohmic contact layer, wherein the passivation layer comprises a plurality of contact holes enabling the first electrode to electrically contact the first conduction type buffer layer and the second electrode to electrically contact the second conduction type ohmic contact layer.

4. The photodiode according to claim 1, further comprising an anti-reflection layer formed on a lower surface of the substrate.

5. The photodiode according to claim 1, wherein the first conduction type buffer layer, the second conduction type field controlling layer, and the second conduction type buffer layer are formed of an InP semiconductor layer, and the second conduction type light-absorbing layer is formed of an InGaAs semiconductor layer.

6. The photodiode according to claim 1, wherein the first conduction type buffer layer is formed of the InP semiconductor layer and an InAlAs semiconductor layer.

7. The photodiode according to claim 1, wherein a total charge density of the second conduction type ion injection layer and the second conduction type field controlling layer is 3×1012/cm²±20%, and a charge density of an edge region, where the ion injection layer is not formed, is 2×1012/cm²±20%.

8. The photodiode according to claim 1, wherein the amplifying layer having the superlattice structure is either formed of one of the InAlAs semiconductor layer and an InAlGaAs semiconductor layer, or formed of the InAlAs semiconductor layer and the InAlGaAs semiconductor layer alternately deposited on each other.

9. The photodiode according to claim 1, wherein the second electrode is formed in a ring structure so as to project a plurality of optical signals toward the second electrode.

10. The photodiode according to claim 1, wherein the substrate is formed of one of a first conduction type InP semiconductor layer and a semi-insulation InP semiconductor layer.

11. A method for fabricating a photodiode, comprising:
preparing a substrate;
serially forming a first conduction type buffer layer, an amplifying layer having a superlattice structure, a second conduction type field controlling layer, and a surface protection layer on the substrate;
injecting ions into the field controlling layer so as to form a second conduction type ion injection layer;
removing the surface protection layer and serially forming a second conduction type light-absorbing layer, a second conduction type field buffer layer, and a second conduction type ohmic contact layer on the field controlling layer;
selectively removing the second conduction type ohmic contact layer, the second conduction type field buffer layer, the second conduction type light-absorbing layer, the second conduction type field controlling layer, and the amplifying layer having the superlattice structure, based on the ion injection layer, so as to expose a surface of the first conduction type buffer layer, thereby forming a mesa structure;
forming a passivation layer on an entire surface of the substrate, so as to form a plurality of contact holes on the ohmic contact layer and the first conduction type buffer layer; and
forming a first electrode and a second electrode electrically contacting the first conduction type buffer layer and the second conduction type ohmic contact layer, respectively, through the contact holes.

12. The method according to claim 11, wherein the forming an ion injection layer further comprises:
ion injecting impurities such as beryllium (Be) or magnesium (Mg) into the field controlling layer; and
activating the injected ions by treating the substrate with a heating process.

13. The method according to claim 12, wherein the heating process is carried out at a temperature in the range of 600 to 700 degrees Celsius (° C.).

14. The method according to claim 11, further comprising carrying out a lapping process and a polishing process, so as to reduce a thickness of the photodiode.

15. The method according to claim 11, further comprising forming an anti-reflection layer on a lower surface of the substrate.

16. The method according to claim 11, wherein the first conduction type buffer layer, the second conduction type field controlling layer, and the second conduction type buffer layer are formed of an InP semiconductor layer, and the second conduction type light-absorbing layer and the second conduction type ohmic contact layer are formed of an InGaAs semiconductor layer.

17. The method according to claim 11, wherein the first conductive type buffer layer is formed by depositing the InP semiconductor layer and an InAlAs semiconductor layer, and the InAlAs semiconductor layer is removed when forming the mesa structure.

18. The method according to claim 11, wherein a total charge density of the second conduction type ion injection layer and the second conduction type field controlling layer is less than or equal to 3×1012/cm²+20%, and a charge density of an edge region, where the ion injection layer is not formed, is 2×1012/cm²±20%.

19. The method according to claim 11, wherein the amplifying layer having the superlattice structure is either formed of one of the InAlAs semiconductor layer and an InAlGaAs semiconductor layer, or formed of the InAlAs semiconductor layer and the InAlGaAs semiconductor layer alternately deposited on each other.

20. A method for fabricating a photodiode, comprising:
preparing a substrate;
serially forming a first conduction type buffer layer, an amplifying layer having a superlattice structure, a second conduction type field controlling layer, a second conduction type light-absorbing layer, a second conduction type field buffer layer, and a second conduction type ohmic contact layer on the substrate;
injecting ions into the field controlling layer so as to form a second conduction type ion injection layer;
selectively removing the second conduction type ohmic contact layer, the second conduction type field buffer layer, the second conduction type light-absorbing layer, the second based on the ion injection layer, conduction type field controlling layer, and the amplifying layer having the superlattice structure, so as to expose a surface of the first conduction type buffer layer, thereby forming a mesa structure;
forming a passivation layer on an entire surface of the substrate, so as to form a plurality of contact holes on the ohmic contact layer and the first conduction type buffer layer; and
forming a first electrode and a second electrode electrically contacting the first conduction type buffer layer and the second conduction type ohmic contact layer, respectively, through the contact holes.

21. The method according to claim 20, further comprising forming an anti-reflection layer on a lower surface of the substrate.

22. The method according to claim 20, wherein the first conduction type buffer layer, the second conduction type field controlling layer, and the second conduction type buffer layer are formed of an InP semiconductor layer, and the second conduction type light-absorbing layer and the second conduction type ohmic contact layer are formed of an InGaAs semiconductor layer.

23. The method according to claim 20, wherein the first conductive type buffer layer is formed by depositing the InP semiconductor layer and an InAlAs semiconductor layer, and the InAlAs semiconductor layer is removed when forming the mesa structure.

24. The method according to claim 20, wherein a total charge density of the second conduction type ion injection layer and the second conduction type field controlling layer is less than or equal to 3×1012cm²±20%, and a charge density of an edge region, where the ion injection layer is not formed, is 2×1012/cm²±20%.

25. The method according to claim 20, wherein the amplifying layer having the superlattice structure is either formed of one of the InAlAs semiconductor layer and an InAlGaAs semiconductor layer, or formed of the InAlAs semiconductor layer and the InAlGaAs semiconductor layer alternately deposited on each other.
